(19) United States
(12) Patent Application Publication
(10) Pub. No.: US 2008/0094800 A1
(43) Pub. Date: Apr. 24, 2008

(54) Heat-dissipating device and method for producing the same

(76) Inventors: Shu-Chuang Chen, Taipei Hsien (TW); Ching-Chih Chen, Taipei Hsien (TW)

Correspondence Address: TROXELL LAW OFFICE PLLC, SUITE 1404, 5205 LEESBURG PIKE, FALLS CHURCH, VA, 22041, US

(21) Appl. No.: 11/583,949

(22) Filed: Oct. 20, 2006

(51) Int. Cl. H05K 7/20; F28D 15/02; F28F 13/00

(52) U.S. Cl. 361/704; 165/185; 29/890.032

(57) ABSTRACT

A heat-dissipating device and a method for producing the same, by forming an accommodating space and a plurality of locating part in communicated with said accommodating space on a metal body that contains a plurality of heat-dissipating fins; disposing a plurality of heat-conducting element in each corresponding locating part; disposing a pressurizing element that is provided over its periphery with a plurality of push-pressing parts into said accommodating space within said metal body, whereupon one end of each push-pressing part will press against the periphery of said heat-conducting element, respectively, to deform said heat-conducting element and thus engage intimately each heat-conducting element with said metal body so as to achieve a heat dissipating effect.

### BACKGROUND OF THE INVENTION

1. Field of the Invention

The invention relates to a heat-dissipating device, and in particular, a heat-dissipating device characterized in that it is composed of a plurality of heat-conducting elements intimately combined within a metal main body that is provided with a plurality of heat-dissipating fins, so as to save material and procession costs, and achieve heat-dissipating effect; and to a method for producing the heat-dissipating device. The heat-dissipating device according to the invention is suitably applicable in computer, communication, electronic instruments and other heat-generating electric products.

2. Description of the Prior Art

As the modern computer and communication technology is progressed quickly, and the working speed of a processor is correspondingly rapidly increased, the high temperature associated with which must be lowered by means of a heat-dissipating device with high performance to maintain a normal working temperature.

Referring to FIG. 1, a conventional heat-dissipating device is shown to be engaged between a processor and a fan, which heat-dissipating device a is composed mainly of a plurality of fins a1 and a heat pipe a2 in the shape of an elongated strip. The heat generated during the operation of the processor can be transferred by the heat pipe a2 to the plurality of fins where the heat can be driven off by the air circulation come from the action of the fan and the temperature can thus be lowered.

As to the manner of engagement between each fin a1 and heat pipe a2 described above, there are primarily two methods, namely, welding and mechanical pressing, such that the heat pipe and each fin can be combined integrally with a certain space between fins. A welding procession as described above can make the heat-dissipating device to achieve the effect of heat dissipating, however, if the material of the heat pipe is different from that of the fins, in the course of welding, an electroplated or chemically plated nickel coating has to be applied on the surface of the heat pipe or fin so as to combine the heat pipe and the fin into an integral body, which will increases invariably the production and the material costs. On the other hand, use of a mechanical pressing to make the heat pipe and fin intimately matched will increase likewise the processing cost from the intimate matching by pressing.

Referring to FIG. 12, another conventional heat-dissipating device b is shown, wherein said heat-dissipating device b is consisted mainly a metal body b1 provided with a plurality of heat-dissipating fin b2. Said metal body b1 is formed by cutting a pultruded aluminum product. A via b3 going from top through bottom is provided on the central area of said metal body b1, and a metal rod b4 (an aluminum rod or a copper rod) is engaged within said via b3. Nevertheless, its heat dissipating effect is not satisfactory. Therefore, a large thermal tower was proposed to displace directly the aluminum rod or copper rod. Unfortunately, in practical application, since the length of said large thermal tower to be used in the heat-dissipating device is too small to yield a good heat dissipating effect, and at the same time, once the thermal tower is inactive, the heat dissipating effect of said heat-dissipating device will lose its heat dissipating effect completely.

In addition, on combining the two types of conventional heat-dissipating device described above with a heat dissipating fan, since the heat-dissipating device itself is not provided with any engaging structure, the heat-dissipating device and the heat dissipating fan can be locked accurately only with aid of an additional fan fixing seat, which not only increases the cost form the material of the fan fixing seat, but also lengthens the time spent for the assembly thereof.

In view of the foregoing, in order to overcome the above-mentioned disadvantages so that the heat-dissipating device and its producing method can not only save material and procession costs, but also achieve the heat dissipating effect, the inventor had studied intensively for many years based on abundant experience and, finally, provided the heat dissipating device and its producing method according to the invention.

### SUMMARY OF THE INVENTION

The main object of the invention is to provide a method for producing a heat-dissipating device, by disposing a pressurizing element that is provided with a plurality of push-pressing parts into an accommodating space within a metal body, whereupon one end of each push-pressing part will press against a respective heat-conducting element provided previously within said metal body, so that each heat-conducting element can be engaged intimately in said metal body so as to achieve a heat dissipating effect.

Another object of the invention is to provide a heat-dissipating device, comprising a plurality of heat-conducting elements intimately engaged in a metal body that is provided therein with a plurality of heat-dissipating fins, thereby forming a structure that can conduct effectively the heat generated during the operation of a processor so as to achieve an effect of dissipating heat, and to assure the normal action of said heat-conducting elements.

Still another object of the invention is to provide a heat-dissipating device, comprising a supporting structure for a plurality of heat-conducting elements, wherein a venting space is formed between a plurality of heat dissipating fins and a processor, so as to dissipate heat quickly by virtue of the action of a heat dissipating fan.

Still yet another object of the invention is to provide a heat-dissipating device, comprising a plurality of locating holes provided around the periphery of a metal body in a manner to screw directly with a heat-dissipating fan so as to minimize the processing process for assembling the heat-dissipating device and the fan, thereby reduce the procession and material costs.

For accomplishing the above-mentioned objects, the inventive method for producing a heat-dissipating device comprises following steps: a. providing a metal body that comprises a plurality of heat-dissipating fins, as well as an accommodating space and a plurality of locating parts in communicating with said accommodating space formed on said metal body; b. disposing each of a plurality of heat-conducting elements in each locating part, respectively; and c. disposing a pressurizing element that is provided around its periphery with a plurality of push-pressing parts into said accommodating space of said metal body in a manner that one end of each push-pressing part squeezes against the periphery of each corresponding heat-conducting element, respectively, thereby deforms each heat-conducting element and hence fixes them in each locating part.

In practice, said pressurizing element is composed of a shaft lever and a plurality of squeezing part, with one end of said squeezing part forming a push-pressing part. In the step c mentioned above, a plurality of squeezing parts is disposed in the accommodating space of said metal body, such that the common end of each squeezing part forms a through hole through which the shaft lever can be pressed into the through hole and pushes each squeezing part, thereby each push-pressing part can squeeze the periphery of each heat-conducting element so as to deform and hence fix each heat-conducting element in each respective locating part. Thus, each heat-conducting element can be engaged intimately against said metal body, and consequently, a heat conducing and dissipating effect can be achieved.

In another aspect, the invention provides a heat-dissipating device, characterized in that it comprises a metal body, a plurality of heat-conducting element and a pressurizing element. Said metal body consists of a plurality of heat dissipating fins, and is provided with an accommodating space and a plurality of locating part in communicating with said accommodating space. Said plurality of heat-conducting elements is disposed in each corresponding locating part. Said pressurizing element is disposed in the accommodating space of said metal body. Said pressurizing element is provided around its periphery with a plurality of push-pressing parts in a manner that one end of each push-pressing part can squeeze the periphery of each heat-conducting element, thereby each heat-conducting element can be deformed and hence fixed in the respective locating part.

In one embedment, said pressurizing element comprises a shaft lever and a plurality of squeezing parts, wherein one end of said squeezing part forms a push-pressing part.

In another embodiment, the heat-dissipating device of the invention comprises further a plurality of locating hole, wherein said locating holes is provided around the periphery of said metal body so as to engage with screws the heat-dissipating fan disposed above. These features and advantages of the present invention will be fully understood and appreciated from the following detailed description of the accompanying drawings.

### BRIEF DESCRIPTION OF THE DRAWINGS

FIG. 1 is a flowchart illustrating the method for producing a heat-dissipating device according to the present invention.

FIG. 2 is an elemental exploded view of a heat-dissipating device according to the first embodiment of the present invention.

FIG. 3 is a top view of a heat-dissipating device according to the first embodiment of the present invention.

FIG. 4 is an elemental exploded view of a heat-dissipating device according to the second embodiment of the present invention.

FIG. 5 is a top view illustrating the formation of a through hole from the common end of each squeezing part in the method for producing the heat-dissipating device according to the present invention.

FIG. 6 is a top view illustrating the penetration of a shaft lever into the through hole to push outwardly against each squeezing part in the method for producing the heat-dissipating device according to the present invention.

FIG. 7 is a top schematic view illustrating the engagement of the L-shaped heat-conducting element with a base plate in the heat-dissipating device according to the present invention.

FIG. 8 is a top view illustrating the engagement of the L-shaped heat-conducting element with the metal body and a base plate in the heat-dissipating device according to the present invention.

FIG. 9 is a schematic view illustrating a state of using the heat-dissipating device according to the present invention.

FIG. 10 is a schematic view illustrating another state of using the heat-dissipating device according to the present invention.

FIG. 11 is a three-dimensional view of a conventional heat dissipater.

FIG. 12 is a three-dimensional view of another conventional heat dissipater.

### DETAILED DESCRIPTION OF THE PREFERRED EMBODIMENT

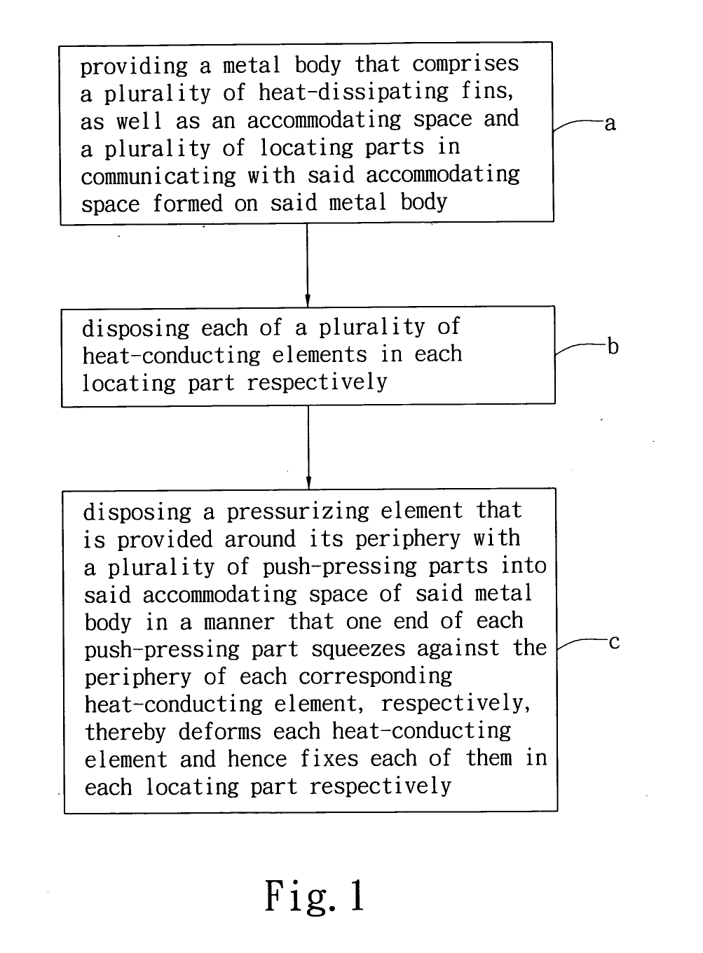

Referring to FIG. 1-3, a preferred embodiment of the method for producing a heat-dissipating device according to the invention comprises following steps:
a. providing a metal body 2 that comprises a plurality of heat-dissipating fins 21, as well as an accommodating space 22 and a plurality of locating parts 23 in communicating with said accommodating space 22 formed on said metal body 2;
b. disposing each of a plurality of heat-conducting elements 3 in each locating part 23, respectively; and
c. disposing a pressurizing element 4 that is provided around its periphery with a plurality of push-pressing parts 41 into said accommodating space 22 of said metal body 2 in a manner that one end of each push-pressing part 41 squeezes against the periphery of each corresponding heat-conducting element 3, respectively, thereby deforms each heat-conducting element 3 and hence fixes each of them in each locating part 23, respectively.

In the step b, said heat-conducting element 3 is a circular heat pipe, wherein ends of any two of said heat-conducting elements 3 is communicated to construct a U-shape, thereby any two of said heat-conducting elements 3 can be inserted into each of the corresponding circular locating parts 23. Whereas in step c, the bottom of said push-pressing part 41 is provided with a undercut to facilitate downward moving of the push-pressing part 41, and the squeezing against the periphery of each heat-conducting element 3.

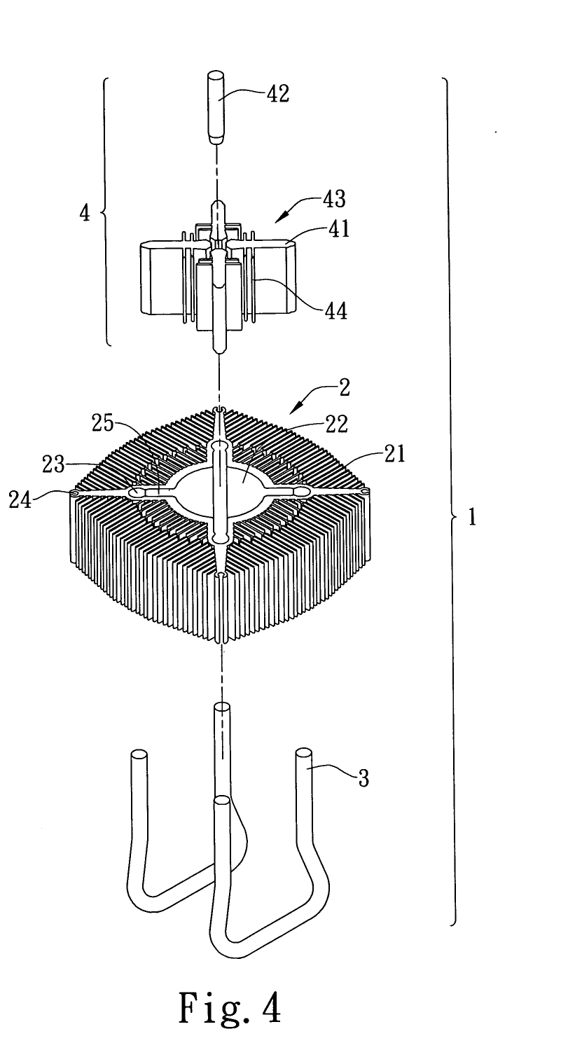

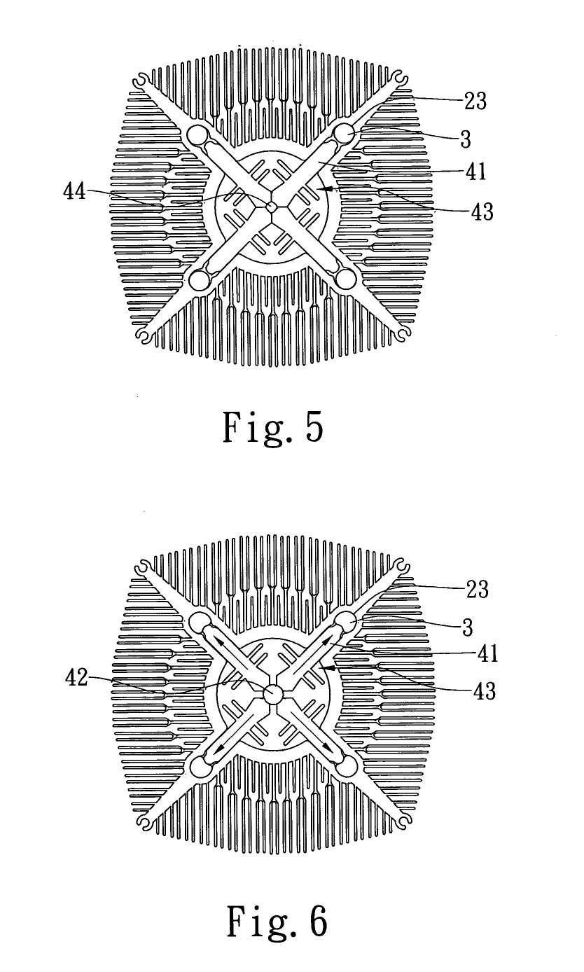

Referring to FIG. 4, in practice, said pressurizing element 4 can comprise alternatively a shaft lever 42 and a plurality of squeezing element 43. One end of said squeezing element 43 forms a push-pressing part 41. Thus, in step c, a plurality of squeezing elements 43 is disposed in the accommodating space 22 of the metal body 2 such that common ends of said squeezing elements 43 form a through hole 44 (as shown in FIG. 5). Upon penetrating into the through hole 44, a shaft lever 42 with a conical end will push outwardly each squeezing elements 43, thereby push the moving squeezing element 41 to squeeze the periphery of each heat-conducting element 3. Thus, each heat-conducting element 3 will be deformed, extended, and hence fixed in each corresponding locating part 23 (as shown in FIG. 6).

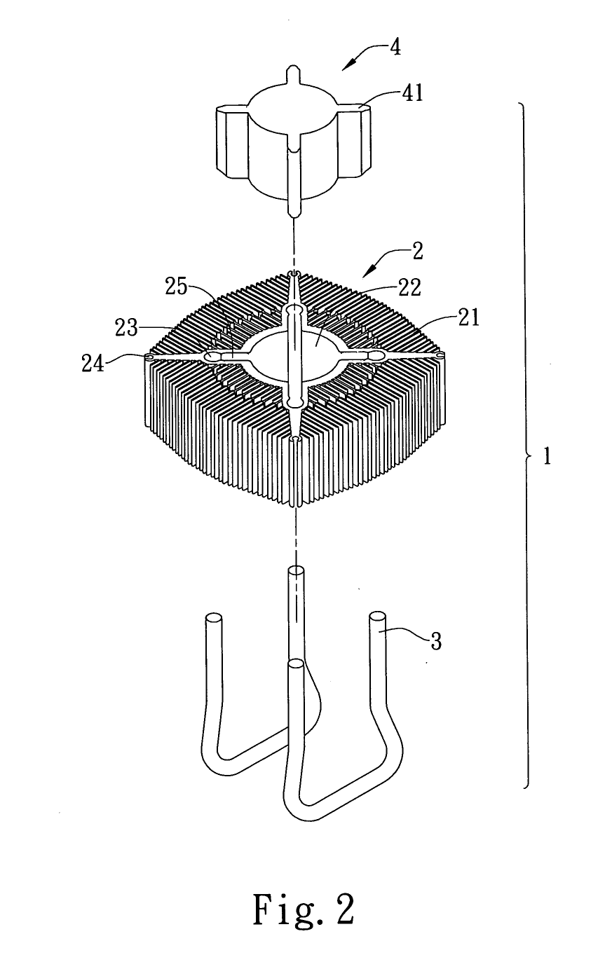

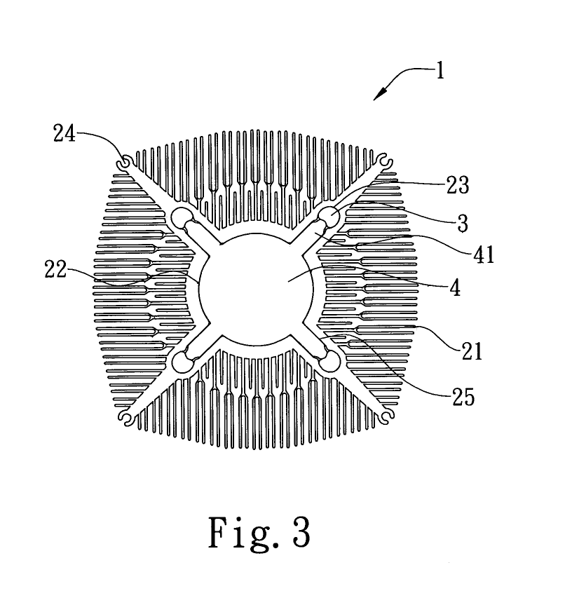

Referring to FIGS. 2 and 3, a heat-dissipating device 1 according to the first embodiment of the invention comprises a metal body 2, a plurality of heat-conducting elements 3 and a pressurizing element 4.

Said metal body 2 is generally square shaped, and comprises a plurality of upright heat-dissipating fins 21. Said metal body 2 is provided on its four corners with a circular locating hole 24, respectively. Said metal body 2 is provided further at its central area with a cylindrical accommodating space 22 in a manner that said for circular hole shaped locating parts 23 are distributed symmetrically around said accommodating space 22 and connect said accommodating space 22 through a elongated channel 25.

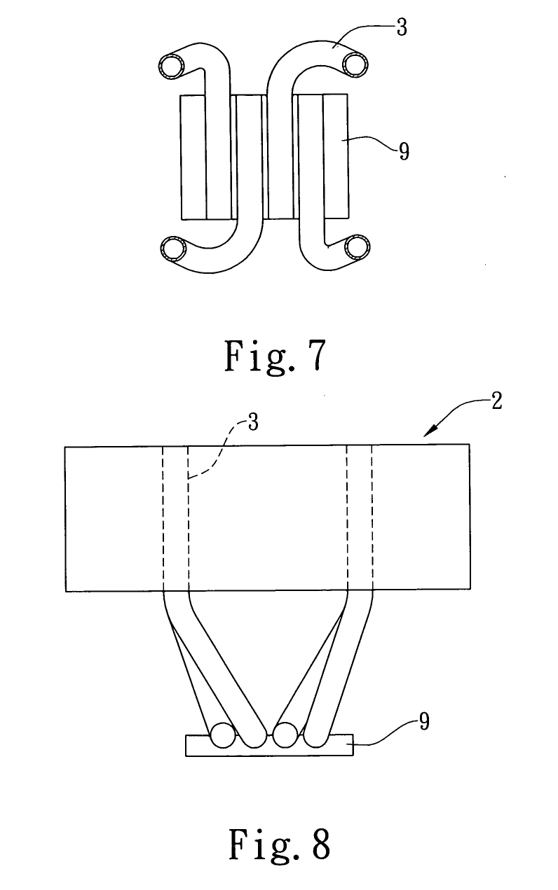

Any two of said heat-conducting elements 3 are formed as two ends of a U-shaped heat pipe. Alternatively, as shown in FIGS. 7 and 8, any said heat-conducting element 3 may be generally as an L shape, with its top end inserted in its corresponding circular locating part 23, while its lower end is located on a heat-conductive base plate 9.

Said pressurizing element 4 is in a cylindrical shape and is provided by extending over its periphery with four push-pressing part 41 in a manner that they can be fitted intimately in the accommodating space 22 of the metal body 2 and in the four peripheral channels 25. One end of each of said four push-pressing parts 41 can squeeze the periphery of corresponding heat-conducting element 3 so as to deform each heat-conducting element 3, and thereby render them fixed in each locating part 23, respectively.

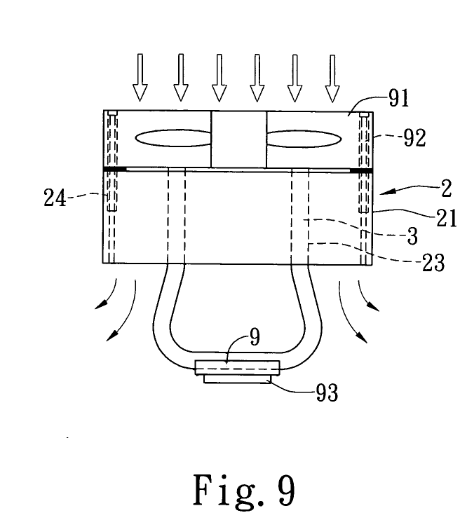

Referring to FIG. 9, in a state of using the heat-dissipating device according to the invention, said heat-dissipating fan 91 is disposed at an elevation higher than the heat-dissipating fins 21. Four screws 92 thread through said heat-dissipating fan 91 to be screwed in the corresponding locating hole 24 on four corners of the metal body 2, such that the heat-dissipating fan 91 can be engaged and located with the metal body 2. The bottom end of said U- or L-shaped heat-conducting elements 3 is fixed on a heat conductive base plate 9. Said base plate 9 is adhered over the top of a processor 93, and thereby, as the processor operates, heat generated therefrom can be transferred from said base plate 9 through each heat-conducting elements 3 to the plurality of fins 21, where, under the action of the fan 91, hot air will flow downwardly, and fins 21 can be cooled down, thereby, heat generated from the operation of the processor 93 can be dissipated very rapidly. Furthermore, in practice, a thermal grease is applied between said heat-conducting elements 3 and said locating part 23 to enhance the heat-dissipating effect.

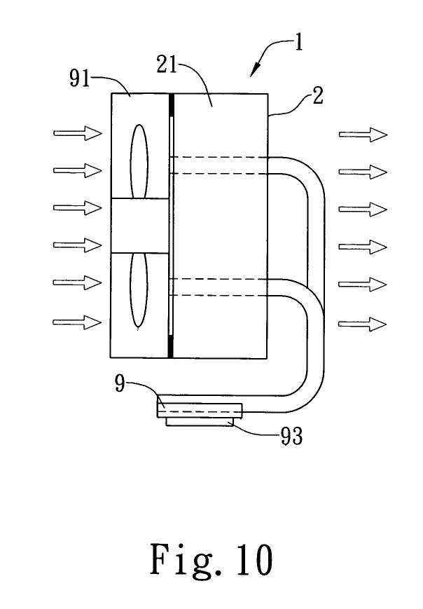

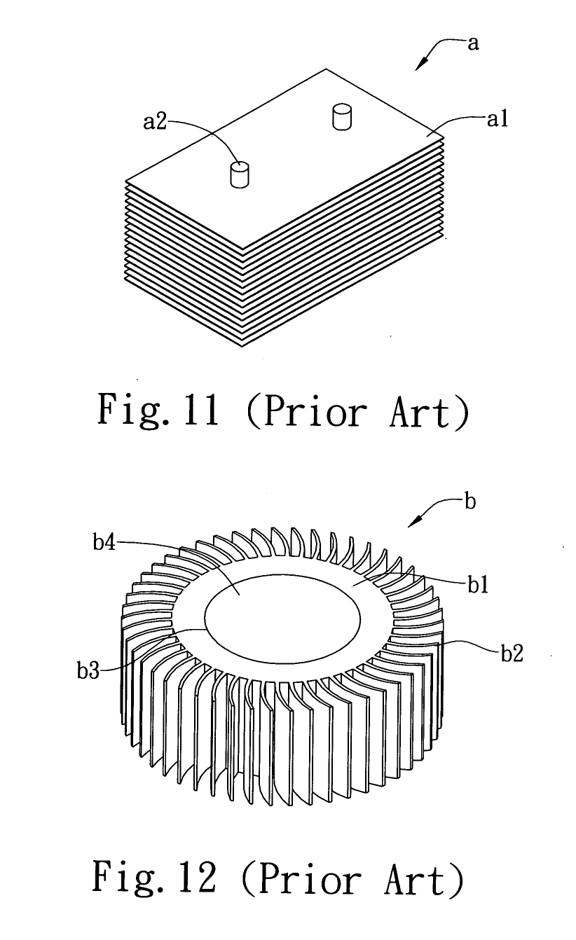

Referring to FIG. 10, another state of using the heat-dissipating device according to the invention, here, the heat-dissipating device 1 is provided upright above a heat-conductive base plate 9. As the heat-dissipating fan is engaged and located with the metal body 2, the operation of the heat-dissipating fan 91 can drive the hot air to flow along horizontal direction. Thus, by virtue of this lateral blow fashion, the fins 21 can be cooled down quickly to achieve the effect of cooling down the processor 93. Further, referring to FIG. 4, a heat-dissipating device according to the second embodiment of the invention is shown, wherein said pressurizing element 4 comprises a circular shaft lever 42 and four squeezing elements 43. Said squeezing element 43 is made preferably of metal material. One end of said squeezing element 43 forms a push-pressing part 41, and is provided on its lateral side with a plurality of symmetrically disposed heat sink 44. Under squeezing by the squeezing part 41, each heat-conducting element 3 can be fixed tightly in each locating part 23 such that each heat-conducting element 3 can be adhered intimately against the metal body 2. Further, by means of several heat sink 44 protruding from the lateral side of the squeezing element 43, the heat-dissipating effect can be enhanced.

In summary, the heat-dissipating device according to the invention can exhibit following advantages:
1. In the heat-dissipating device, each heat pipe can be engaged intimately in the metal body, and by virtue of the quick heat conducting property of each heat pipe, heat generated during operation of a processor can be reduced effectively, and hence the service life of the product can be extended.
2. In the heat dissipating device according to the invention, a metal body can engaged multiple heat pipes, whereby, if any heat pipe among them is inactive, the remaindering heat pipes can accomplish the heat-dissipating effect to assure the normal operation of the processor.
3. In the heat dissipating device according to the invention, a gap can be formed between a plurality of heat-dissipating fins and a processor, such that, as the operation of the heat-dissipating fan drives hot air to flow downwardly, heat on these heat-dissipating fins can be dissipated rapidly.
4. In the heat dissipating device according to the invention, the heat-dissipating device can be engaged and fixed with the metal body, thereby the assembly process can be simplified effectively and the cost of materials can be lowered.

Accordingly, based on the above disclosure, it is apparent that the invention can attain intended objects thereof, and provides a heat-dissipating device and a method for producing the same that not only can save effectively the cost, but also achieve an effect of heat dissipating. The invention is thus valuable for industrial application and meets the requirement of a patent.

Many changes and modifications in the above-described embodiment of the invention can be carried out without departing from the scope thereof. Accordingly, to promote the progress in science and the useful arts, the invention is disclosed and is intended to be limited only by the scope of the appended claims.

What is claimed is:

1. A method for producing a heat-dissipating device, comprising following steps:
a. providing a metal body 2 that comprises a plurality of heat-dissipating fins 21, as well as an accommodating space 22 and a plurality of locating parts 23 in communicating with said accommodating space 22 formed on said metal body 2;
b. disposing each of a plurality of heat-conducting elements 3 in each locating part 23, respectively; and
c. disposing a pressurizing element 4 that is provided around its periphery with a plurality of push-pressing parts 41 into said accommodating space 22 of said metal body 2 in a manner that one end of each push-pressing part 41 squeezes against the periphery of each corresponding heat-conducting element 3, respectively, thereby deforms each heat-conducting element 3 and hence fixes them in each locating part 23.

2. The method for producing a heat-dissipating device as claimed in claim 1, wherein, said heat-conducting element is a heat pipe.

3. The method for producing a heat-dissipating device as claimed in claim 1, wherein any two of said heat-conducting elements is in communicated with each other.

4. The method for producing a heat-dissipating device as claimed in claim 1, wherein said pressurizing element comprises a shaft lever and a plurality of squeezing element, one end of said squeezing element form a push-pressing part.

5. The method for producing a heat-dissipating device as claimed in claim 4, wherein in step c, a plurality of squeezing elements 43 is disposed in the accommodating space 22 of the metal body 2 such that common ends of said squeezing elements 43 form a through hole 44, and, upon penetrating into the through hole 44, said shaft lever 42 pushes outwardly each squeezing elements 43, thereby push said moving squeezing element 41 to squeeze the periphery of each heat-conducting element 3 such that each heat-conducting element 3 is deformed and hence fixed in each of them corresponding locating part 23, respectively.

6. A heat-dissipating device, characterized in that it comprises:
a metal body, consisting of a plurality of heat dissipating fins, and provided with an accommodating space and a plurality of locating parts in communicating with said accommodating space;
a plurality of heat-conducting element, disposed in each corresponding locating part; and
a pressurizing element, disposed in the accommodating space of said metal body, and provided around its periphery with a plurality of push-pressing parts in a manner that one end of each push-pressing part can squeeze the periphery of each heat-conducting element, thereby each heat-conducting element can be deformed and hence fixed in the respective locating part.

7. The heat-dissipating device as claimed in claim 6, wherein said heat-conducting element is a heat pipe.

8. The heat-dissipating device as claimed in claim 6, wherein any two of said heat-conducting elements is in communicated with each other.

9. The heat-dissipating device as claimed in claim 6, wherein said pressurizing element comprises a shaft lever and a plurality of squeezing element, one end of said squeezing element form a push-pressing part.

10. The heat-dissipating device as claimed in claim 9, wherein said squeezing element is provided further on its lateral side with a heat sink.

11. The heat-dissipating device as recited in claim 6, comprising further a plurality of locating holes that is provided separately over the periphery of said metal body.
